(19) United States
(12) Patent Application Publication
(10) Pub. No.: US 2024/0371954 A1
(43) Pub. Date: Nov. 7, 2024

(54) SEMICONDUCTOR DEVICE HAVING REDUCED NOISE AND METHOD OF MANUFACTURING THE SAME

(71) Applicant: TAIWAN SEMICONDUCTOR MANUFACTURING COMPANY LTD., HSINCHU (TW)

(72) Inventors: WAN-LIN TSAI, HSINCHU CITY (TW); CLEMENT HSINGJEN WANN, CARMEL, NY (US); YI-JING LI, HSINCHU CITY (TW); I-SHENG CHEN, TAIPEI CITY (TW); SHIH-CHUN FU, HSINCHU CITY (TW); KAI-QIANG WEN, HSINCHU (TW)

(21) Appl. No.: 18/313,360

(22) Filed: May 7, 2023

(51) Int. Cl. H01L 29/417; H01L 27/088; H01L 29/40

(52) U.S. Cl. CPC H01L 29/41791; H01L 27/0207; H01L 27/0886; H01L 29/401

(57) ABSTRACT

The present disclosure provides a semiconductor device and a method of manufacturing the same. The semiconductor device includes a substrate, an active region on the substrate, and a first transistor having a gate structure, a source conductor, and a drain conductor disposed on the active region, wherein the drain conductor and the source conductor are disposed on opposite sides of the gate structure, and the source conductor is shorter than the drain conductor.

### BACKGROUND

With the rapid growth of the electronics industry, the development of integrated circuits (ICs) consistently seeks improvements in performance and miniaturization. Technological advances in IC materials and design have produced generations of ICs in which each generation has smaller and more complex circuits than the previous generation. Transistors and passive components such as resistors, capacitors, and inductors are commonly used as fundamental construction building blocks for ICs. Since area occupied by a component is usually considered a cost in the semiconductor manufacturing industry, the dimensions of passive components are of prime consideration in IC layout. A semiconductor device free from the constraints imposed by dimensions of passive components is therefore called for.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a diagram illustrating a concept of area reduction in IC layout design, in accordance with some embodiments.

FIG. 2 illustrates a circuit that can benefit from the proposed layout design, in accordance with some embodiments.

FIG. 3 illustrates a layout of a semiconductor device including a transistor and an embedded resistor, in accordance with some embodiments.

FIG. 4A is a cross section along the dashed line A-A′ of FIG. 3, in accordance with some embodiments.

FIG. 4B is a cross section along the dashed line B-B′ of FIG. 3, in accordance with some embodiments.

FIG. 5 illustrates a layout of a semiconductor device including a transistor and an embedded resistor, in accordance with some embodiments.

FIG. 6 is a cross section along the dashed line C-C′ of FIG. 5, in accordance with some embodiments.

FIG. 7 illustrates a layout of a semiconductor device including a transistor and an embedded resistor, in accordance with some embodiments.

FIG. 8 illustrates a layout of a semiconductor device including a transistor and an embedded resistor, in accordance with some embodiments.

FIG. 9 illustrates a layout of a semiconductor device including a transistor and an embedded resistor, in accordance with some embodiments.

FIG. 10 illustrates a layout of a semiconductor device including a transistor and an embedded resistor, in accordance with some embodiments.

FIG. 11 illustrates a layout of a semiconductor device including a transistor and an embedded resistor, in accordance with some embodiments.

FIG. 12 is a flowchart of a method of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

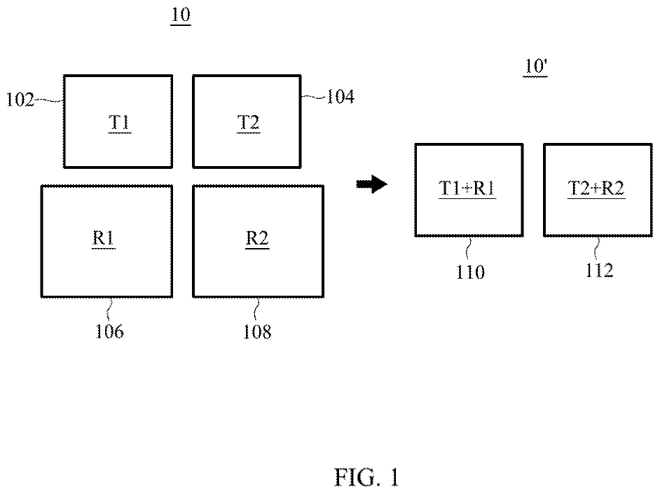

FIG. 1 is a diagram illustrating a concept of area reduction in IC layout design, in accordance with some embodiments. FIG. 1 shows two IC layouts 10 and 10′. IC layout 10 includes regions 102. 104, 106, and 108. Active components, such as transistors T1 and T2, can be located within the regions 102 and 104. Passive components, such as resistors R1 and R2, can be located within the regions 106 and 108. The IC layout 10′ includes regions 110 and 112. A hybrid component including an active component (e.g., transistor T1) and a passive component (e.g., resistor R1) can be located within the region 110. Similarly, another hybrid component including an active component (e.g., transistor T2) and a passive component (e.g., resistor R2) can be located within the region 112.

The IC layout 10′ includes the same number of components (i.e., two transistors and two resistors) as IC layout 10, but can occupy less overall area on the semiconductor wafer. With the hybrid components introduced in the IC layout 10′, an area reduction exceeding 50% can be achieved.

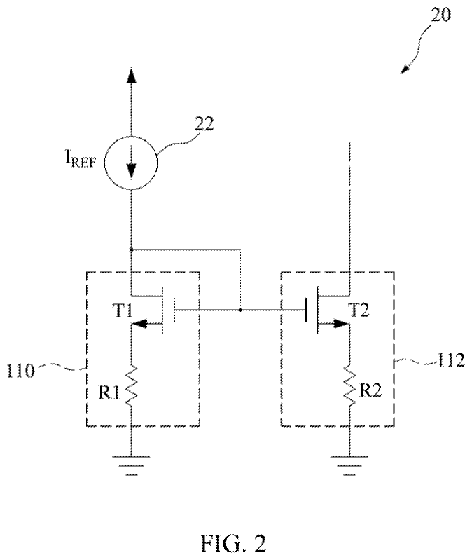

FIG. 2 illustrates a circuit that can benefit from the proposed layout design, in accordance with some embodiments. FIG. 2 shows a current mirror circuit 20. The current mirror circuit 20 includes transistors T1 and T2, resistors R1 and R2, and a current source 22. The resistor R1 is electrically connected to the source terminal of the transistor T1. The resistor R2 is electrically connected to the source terminal of the transistor T2. The gate terminal of the transistor T1 is electrically connected to the drain terminal of the transistor T1. The current source 22 is electrically connected to the drain terminal of the transistor T1. The gate terminal of the transistor T1 is electrically connected to the gate terminal of the transistor T2.

The current mirror circuit 20 can be utilized in a current-controlled oscillator (ICO), in which the resistors R1 and R2 can be referred to as a “source degeneration” mechanism that can reduce the noise of the ICO. The resistors R1 and R2 can be selected to be the same (for example, resistor Rs) in the “source degeneration” mechanism for ICO, and can improve the noise current of the ICO by a factor “1+gm*Rs.” The parameter “gm” represents the transconductance of the transistors T1 and T2, and the Rs is selected to be greater than 1/gm.

In traditional layout design for the current mirror circuit 20, resistors R1 and R2 usually occupy regions different from those for transistors T1 and T2 (for example, see the IC layout 10 of FIG. 1). The IC layout 10 can be considered less area-efficient. On the contrary, if the resistor R1 and the transistor T1 can be located within the same region 110, and the resistor R2 and the transistor T2 can be located within the same region 112, as those arranged in the IC layout 10′ of FIG. 1, the area usage of the ICO on a semiconductor wafer can be reduced.

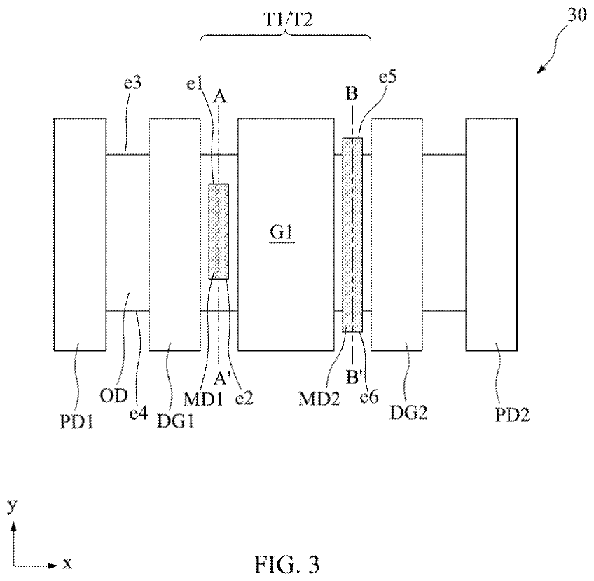

The transistor T1 and the resistor R1 within the region 110 can be implemented by any one of the layout structures shown in FIGS. 3, 5, 7, 8, 9, 10, and 11. The transistor T2 and the resistor R2 within the region 112 can be implemented by any one of the layout structures shown in FIGS. 3, 5, 7, 8, 9, 10, and 11.

FIG. 3 illustrates a layout of a semiconductor device including a transistor and an embedded resistor, in accordance with some embodiments. The layout 30 shown in FIG. 3 pertains to a semiconductor device including a transistor and a resistor. The layout 30 can correspond to a top view perspective of a semiconductor device including a transistor and a resistor. The layout 30 includes an active region OD, a gate structure G1, a source conductor MD1, a drain conductor MD2, dummy gate structures DG1 and DG2, and poly structures PD1 and PD2. The active region OD can also be referred to as oxide difussion region OD. The poly structures PD1 and PD2 can be referred to as poly structures on OD edges, or simplified as “PODE.”

The source conductor MD1 and the drain conductor MD2 are disposed on opposite sides of the gate structure G1. The source conductor MD1 along a y-axis is shorter than the drain conductor MD2 along the y-axis. Since the lengths of the source conductor MD1 and the drain conductor MD2 are different, the semiconductor device manufactured in accordance with the layout 30 can be referred to as a device with imbalanced source/drain conductors.

The source conductor MD1 includes edges e1 and e2, the active region OD includes edges e3 and e4, and the drain conductor MD2 includes edges e5 and e6. The edges e3 and e4 of the active region OD can also be referred to as boundaries e3 and e4. The edge e1 of the source conductor MD1 is misaligned with the edge e3 of the active region OD, and edge e2 of the source conductor MD1 is misaligned with the edge e4 of the active region OD. The edge e1 of the source conductor MD1 can be located between the edges e3 and e4 of the active region OD, and the edge e2 of the source conductor MD1 can be located between the edges e3 and e4 of the active region OD.

The edge e5 of the drain conductor MD2 is misaligned with the edge e3 of the active region OD, and edge e6 of the drain conductor MD2 is misaligned with the edge e4 of the active region OD. The edges e5 and e6 of the drain conductor MD2 are both outside the area (e.g., defined by edges e3 and e4) of the active region OD. The edge e1 of the source conductor MD1 is misaligned with the edge e5 of the drain conductor MD2, and edge e2 of the source conductor MD1 is misaligned with the edge e6 of the drain conductor MD2.

In some embodiments, the drain conductor MD2 are disposed over a single active region OD. In some embodiments, the drain conductor MD2 will not extend to another active region (not shown) that is adjacent to the active region OD depicted in FIG. 3.

Compared to the drain conductor MD2, the shorter source conductor MD1 carries higher resistance, and thus the source conductor MD1, the gate structure G1, and the drain conductor MD2 can constitute a transistor T1/T2 having a resistor electrically connected to the source of the transistor T1/T2. In some embodiments, the length of the source conductor MD1 can range from 0.1 times to 0.9 times that of the drain conductor MD2. In some embodiments, when the length of the source conductor MD1 is 0.6 times that of the drain conductor MD2, the source conductor MD1 can be equivalent to a resistor of 900Ω. In some embodiments, when the length of the source conductor MD1 is 0.2 that of the drain conductor MD2, the source conductor MD1 can be equivalent to a resistor of 5.3 kΩ.

In some embodiments, the length of the source conductor MD1 (i.e., along the y-axis) can range from 0.01 μm to 5 μm. In some embodiments, the width of the gate structure G1 (i.e., along the x-axis) can range from 0.001 μm to 10 μm. The poly structures PD1 and PD2 can be useful in process control during manufacturing. The dummy gate structures DG1 and DG2 are optional (i.e., not mandatory in the layout 30) and can be useful in reducing layout dependence effects.

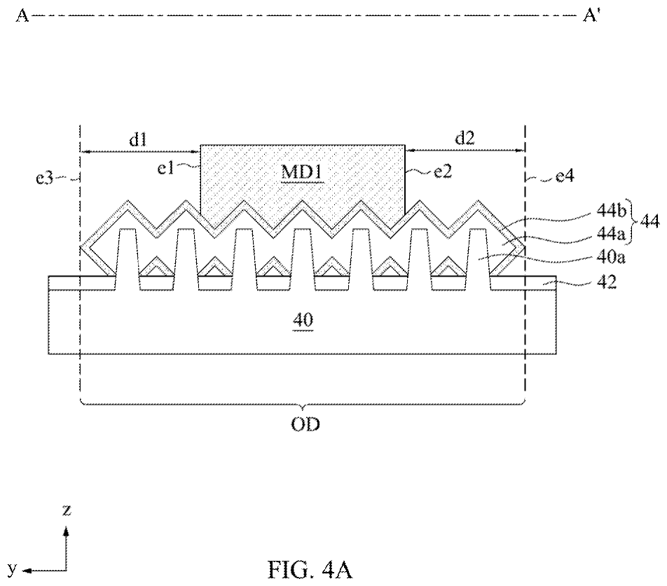

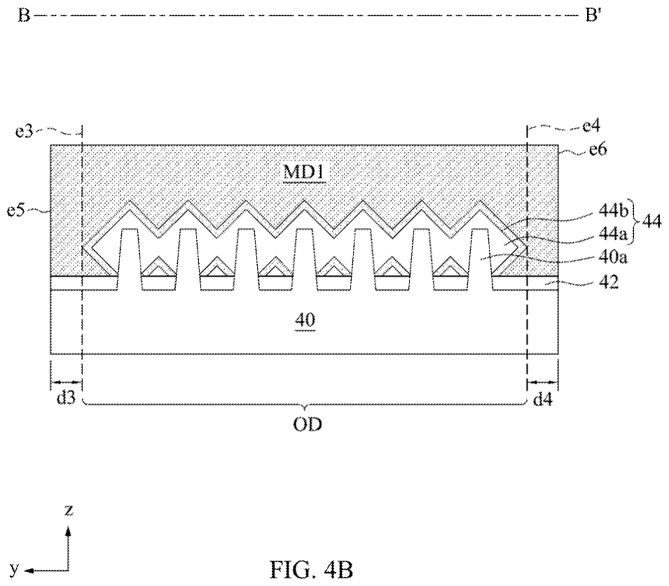

FIG. 4A is a cross section along the dashed line A-A′ of FIG. 3, in accordance with some embodiments. FIG. 4A shows a semiconductor structure including a substrate 40, an isolation layer 42, fin structures 40a, source/drain (S/D) structures 44, and the source conductor MD1. The fin structures 40a protrude from the substrate 40 and are separated by the isolation layer 42. The fin structures 40a extend from the substrate 40 and are separated by the isolation layer 42. Source/drain structure(s) or S/D structure(s) may refer to a source structure or a drain structure, individually or collectively dependent upon the context.

In some embodiments, the substrate 40 is a bulk substrate that includes silicon. Alternatively or additionally, the bulk substrate includes another elementary semiconductor, such as germanium; a compound semiconductor, such as silicon carbide, silicon phosphide, gallium arsenide, gallium phosphide, indium phosphide, indium arsenide, indium antimonide, zinc oxide, zinc selenide, zinc sulfide, zinc telluride, cadmium selenide, cadnium sulfide, and/or cadmium telluride; an alloy semiconductor, such as SiGe, SiPC, GaAsP. AlInAs, AlGaAs, GalnAs, GalnP, and/or GalnAsP; other group III-V materials; other group II-IV materials; or combinations thereof. Alternatively, the substrate 40 can be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

Fin structures 40a are oriented substantially parallel to one another. The fin structures 40a can be a portion of substrate 40. Fin structures 40a are formed by any suitable process including various deposition, photolithography, and/or etching processes. An exemplary photolithography process includes forming a photoresist layer (resist) overlying substrate 40, exposing the resist to a pattern, performing a post-exposure bake process, and developing the resist to form a masking element including the resist. The masking element is then used to etch the fin structure into substrate 40. Areas not protected by the masking element are etched using reactive ion etching (RIE) processes and/or other suitable processes. In some embodiments, fin structures 40a are formed by patterning and etching a portion of the substrate 40. In some other embodiments, fin structures 40a are formed by patterning and etching a silicon layer deposited overlying an insulator layer (for example, an upper silicon layer of a silicon-insulator-silicon stack of an SOI substrate). As an alternative to traditional photolithography, fin structures 40a can be formed by a double-patterning lithography (DPL) process. DPL is a method of constructing a pattern on a substrate by dividing the pattern into two interleaved patterns. DPL allows enhanced feature (e.g., fin) density. Various DPL methodologies include double exposure (e.g., using two mask sets), forming spacers adjacent features and removing the features to provide a pattern of spacers, resist freezing, and/or other suitable processes. It is understood that multiple parallel fin structures 40a may be formed in a similar manner.

Isolation layer 42 electrically isolates active device regions and/or passive device regions of a semiconductor device (e.g., the transistor T1/T2). Isolation layer 42 can be configured with different structures, such as shallow trench isolation (STI), deep trench isolation (DTI), local oxidation of silicon (LOCOS), or combinations thereof. Isolation layer 42 includes an isolation material, such as silicon oxide, silicon nitride, silicon oxynitride, other suitable isolation materials (for example, including silicon, oxygen, nitrogen, carbon, and/or other suitable isolation constituent), or combinations thereof. In some embodiments, isolation layer 42 is multilayered, such as with a bulk dielectric layer disposed over a liner dielectric layer, where the bulk dielectric layer and the liner dielectric layer include materials depending on design requirements. In some embodiments, isolation layer 42 includes a dielectric layer disposed over a doped liner layer (including, for example, boron silicate glass (BSG) and/or phosphosilicate glass (PSG)). Isolation layer 42 is deposited by CVD, physical vapor deposition (PVD), atomic layer deposition (ALD), high density plasma CVD (HDPCVD), metal organic CVD (MOCVD), remote plasma CVD (RPCVD), PECVD, LPCVD, atomic layer CVD (ALCVD), atmospheric pressure CVD (APCVD), other suitable deposition process, or combinations thereof. A planarization process, such as a chemical mechanical polishing (CMP) process, can be performed on isolation layer 42.

The S/D structures 44 are epitaxially grown in the S/D region of fin structures 40a. In some embodiments, each S/D structure 44 is a cladding S/D feature and may comprise an epitaxial (EPI) S/D feature 44a and a silicide layer 44b. For example, semiconductor material is epitaxially grown on fin structures 40a, forming EPI S/D features 44a. Each of the S/D structures 44 covers a portion of one of the plurality of fin structures 40a.

Referring to FIG. 4A, the area within which the S/D structure 44 located can be defined as the active region OD. The active region OD includes edges e3 and e4. The edges e3 and e4 of the active region OD can also be referred to as boundaries e3 and e4. The source conductor MD1 includes edges e1 and e2. The edge e1 of the source conductor MD1 is misaligned with the edge e3 of the active region OD. The edge e2 of the source conductor MD1 is misaligned with the edge e4 of the active region OD. The edges e1 and e2 of the source conductor MD1 are both within the area (e.g., defined by the edges e3 and e4) of the active region OD. A distance d1 exists between the edge e1 of the source conductor MD1 and the edge e3 of the active region OD. A distance d2 exists between the edge e2 of the source conductor MD1 and the edge e4 of the active region OD. In some embodiments, the distance d1 is substantially identical to the distance d2. In other embodiments, the distance d1 is different from the distance d2.

The source conductor MD1 covers some of the S/D structures 44 and exposes some of the S/D structures 44. The source conductor MD1 contacts some of the S/D structures 44, and is isolated/separated from some of the S/D structures 44.

FIG. 4B is a cross section along the dashed line B-B′ of FIG. 3, in accordance with some embodiments.

FIG. 4B shows a semiconductor structure including a substrate 40, an isolation layer 42, fin structures 40a, S/D structures 44, and the drain conductor MD2. The fin structures 40a protrude from the substrate 40 and are separated by the isolation layer 42. The fin structures 40a extend from the substrate 40 and are separated by the isolation layer 42.

Referring to FIG. 4B, the area within which the S/D structure 44 located can be defined as the active region OD. The active region OD includes edges e3 and e4. The edges e3 and e4 of the active region OD can also be referred to as boundaries e3 and e4. The drain conductor MD2 includes edges e5 and e6. The edge e5 of the drain conductor MD2 is misaligned with the edge e3 of the active region OD. The edge e6 of the drain conductor MD2 is misaligned with the edge e4 of the active region OD. The edges e5 and e6 of the drain conductor MD2 are both outside the area (e.g., defined by the edges e3 and e4) of the active region OD.

A distance d3 exists between the edge e5 of the drain conductor MD2 and the edge e3 of the active region OD. A distance d4 exists between the edge e6 of the drain conductor MD2 and the edge e4 of the active region OD. In some embodiments, the distance d3 is substantially identical to the distance d4. In other embodiments, the distance d3 is different from the distance d4. The drain conductor MD2 covers all the S/D structures 44. The drain conductor MD2 contacts all the S/D structures 44.

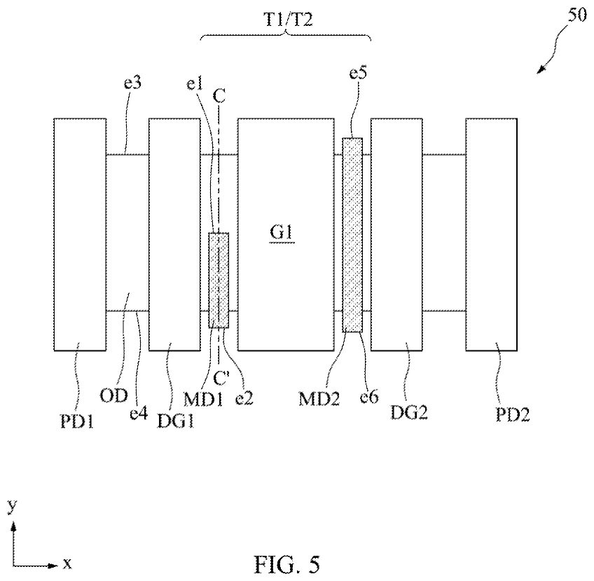

FIG. 5 illustrates a layout of a semiconductor device including a transistor and an embedded resistor, in accordance with some embodiments. The layout 50 shown in FIG. 5 pertains to a semiconductor device including a transistor and a resistor. The layout 50 can correspond to a top view perspective of a semiconductor device including a transistor and a resistor. The layout 50 includes an active region OD, a gate structure G1, a source conductor MD1, a drain conductor MD2, dummy gate structures DG1 and DG2, and poly structures PD1 and PD2.

The source conductor MD1 and the drain conductor MD2 are disposed on opposite sides of the gate structure G1. The source conductor MD1 along the y-axis is shorter than the drain conductor MD2 along the y-axis. Since the lengths of the source conductor MD1 and the drain conductor MD2 are different, the semiconductor device manufactured in accordance with the layout 50 can be referred to as a device with imbalanced source/drain conductors.

The source conductor MD1 includes edges e1 and e2, the active region OD includes edges e3 and e4, and the drain conductor MD2 includes edges e5 and e6. The edges e3 and e4 of the active region OD can also be referred to as boundaries e3 and e4. The edge e1 of the source conductor MD1 is misaligned with the edge e3 of the active region OD, and edge e2 of the source conductor MD1 is misaligned with the edge e4 of the active region OD. The edge e1 of the source conductor MD1 can be located between the edges e3 and e4 of the active region OD, and the edge e2 of the source conductor MD1 can be located outside the area (e.g., defined by edges e3 and e4) of the active region OD. The source conductor MD1 can extend outside the area of the active region OD.

The edge e5 of the drain conductor MD2 is misaligned with the edge e3 of the active region OD, and edge e6 of the drain conductor MD2 is misaligned with the edge e4 of the active region OD. The edges e5 and e6 of the drain conductor MD2 are both outside the area (e.g., defined by edges e3 and e4) of the active region OD. The edge e1 of the source conductor MD1 is misaligned with the edge e5 of the drain conductor MD2, and edge e2 of the source conductor MD1 is aligned with the edge e6 of the drain conductor MD2.

In some embodiments, the drain conductor MD2 are disposed over a single active region OD. In some embodiments, the drain conductor MD2 will not extend to another active region (not shown) that is adjacent to the active region OD depicted in FIG. 5.

Compared to the drain conductor MD2, the shorter source conductor MD1 provides higher resistance, and thus the source conductor MD1, the gate structure G1, and the drain conductor MD2 can constitute a transistor T1/T2 having a resistor electrically connected to the source of the transistor T1/T2. In some embodiments, the source conductor MD1 can be 0.1 to 0.9 times the length of the drain conductor MD2. In some embodiments, when the length of the source conductor MD1 is 0.6 that of the drain conductor MD2, the source conductor MD1 can be equivalent to a resistor of 900Ω. In some embodiments, when the length of the source conductor MD1 is 0.2 that of the drain conductor MD2, the source conductor MD1 can be equivalent to a resistor of 5.3 KΩ.

In some embodiments, the length of the source conductor MD1 (i.e., along the y-axis) can range from 0.01 μm to 5 μm. In some embodiments, the width of the gate structure G1 (i.e., along the x-axis) can range from 0.001 μm to 10 μm. The poly structures PD1 and PD2 can be useful in process control during manufacturing. The dummy gate structures DG1 and DG2 are optional (i.e., not mandatory in the layout 50) and can be useful in reducing layout dependence effect.

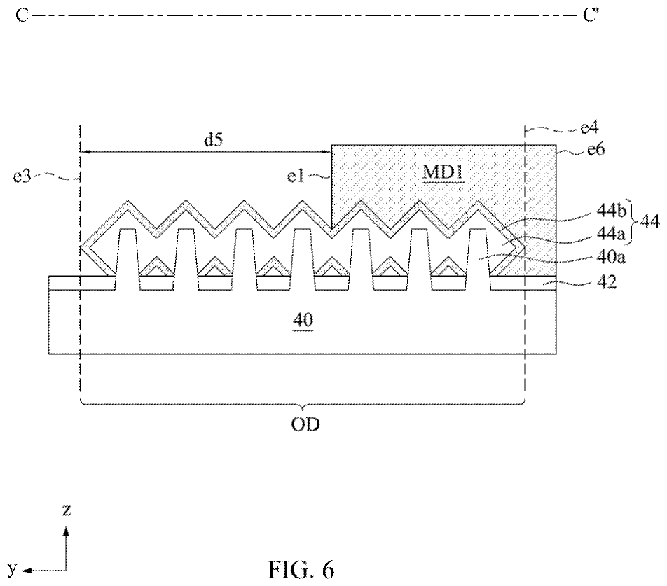

FIG. 6 is a cross section along the dashed line C-C′ of FIG. 5, in accordance with some embodiments. FIG. 6 shows a semiconductor structure including a substrate 40, an isolation layer 42, fin structures 40a, S/D structures 44, and the source conductor MD1. The fin structures 40a protrude from the substrate 40 and are separated by the isolation layer 42. The fin structures 40a extend from the substrate 40 and are separated by the isolation layer 42.

Referring to FIG. 6, the area within which the S/D structure 44 located can be defined as the active region OD. The active region OD includes edges e3 and e4. The edges e3 and e4 of the active region OD can also be referred to as boundaries e3 and e4. The source conductor MD1 includes edges e1 and e2. The edge e1 of the source conductor MD1 is misaligned with the edge e3 of the active region OD. The edge e2 of the source conductor MD1 is misaligned with the edge e4 of the active region OD.

The edge e1 of the source conductor MD1 can be located between the edges e3 and e4 of the active region OD, and the edge e2 of the source conductor MD1 can be located outside the area (e.g., defined by edges e3 and e4) of the active region OD.

A distance d5 exists between the edge e1 of the source conductor MD1 and the edge e3 of the active region OD. The source conductor MD1 covers some of the S/D structures 44 and exposes some of the S/D structures 44. The source conductor MD1 contacts some of the S/D structures 44, and is isolated/separated from some of the S/D structures 44.

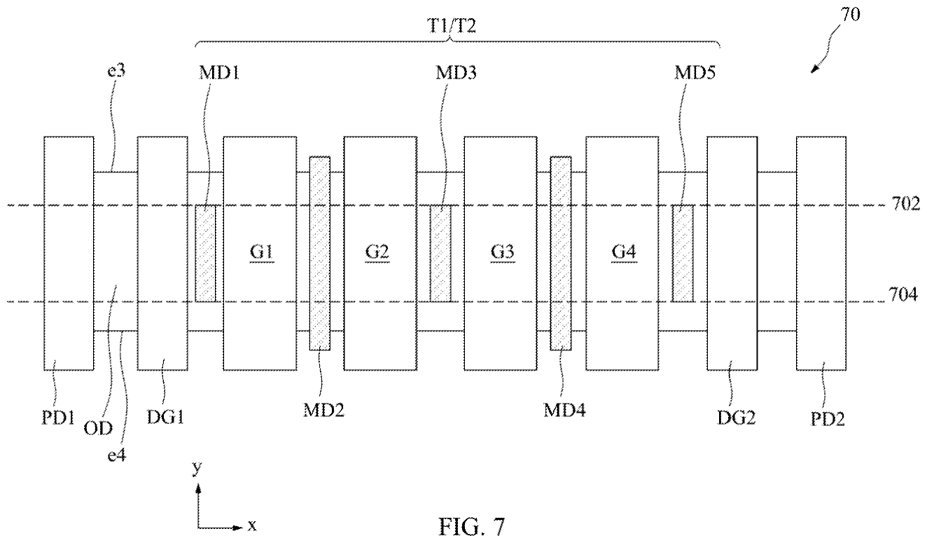

FIG. 7 illustrates a layout of a semiconductor device including a transistor and an embedded resistor, in accordance with some embodiments.

The layout 70 shown in FIG. 7 pertains to a semiconductor device including a transistor and a resistor. The layout 70 can correspond to a top view perspective of a semiconductor device including a transistor and a resistor. The layout 70 includes an active region OD, gate structures G1, G2, G3, and G4, source conductors MD1, MD3, and MD5, drain conductors MD2 and MD4, dummy gate structures DG1 and DG2, and poly structures PD1 and PD2.

In some embodiments, the gate structures G1, G2, G3, and G4 can be electrically connected to the same voltage reference. The gate structures G1, G2, G3, and G4 can be electrically connected through upper-layered interconnections (not shown). The source conductors MD1, MD3, and MD5 can be electrically connected to the same voltage reference. The source conductors MD1, MD3, and MD5 can be electrically connected through upper-layered interconnections (not shown). The drain conductors MD2 and MD4 can be electrically connected to the same voltage reference. The drain conductors MD2 and MD4 can be electrically connected through upper-layered interconnections (not shown).

The layout 70 can be associated with a transistor having a multi-finger structure. The shorter source conductors MD1, MD3, and MD5 each provides higher resistance than the drain conductors MD2 and MD4. With the multi-finger structure shown in FIG. 7, the resistance of the equivalent resistor constituted by the source conductors MD1, MD3, and MD5 can be adjusted according to need. For example, when high resistance is needed in the source degeneration applications, a transistor can include a single short source conductor MD1. Alternatively, several short source conductors (e.g., MD1, MD3, and MD5) can be connected in parallel so as to achieve relatively lower resistance in another application. In still other embodiments, some of the short source conductors (e.g., MD1. MD3, and MD5) can be connected in series so as to achieve a target resistance.

In the embodiment shown in FIG. 7, the source conductors MD1, MD3, and MD5 are disposed within the area (e.g., defined by edges e3 and e4) of the active region OD. The source conductors MD1, MD3, and MD5 can be aligned, wherein each includes one edge aligned with the dashed line 702 and another edge aligned with the dashed line 704. Although a specific number (i.e., 3) of source conductors is depicted in FIG. 7, it can be contemplated that the number of source conductors can be adjusted in accordance with actual design needs. Similarly, the numbers of drain conductors and the gate structures can be adjusted in accordance with actual design needs. In some embodiments, the number of the gate structures can range from 2 to 300.

In some embodiments, the drain conductors MD2 and MD4 are disposed over a single active region OD. In some embodiments, the drains conductor MD2 and MD4 will not extend to another active region (not shown) that is adjacent to the active region OD depicted in FIG. 7.

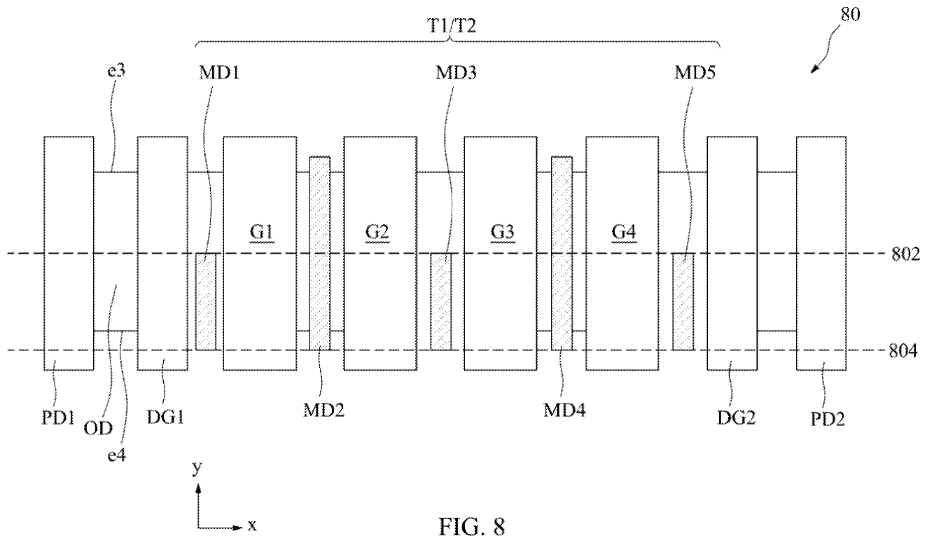

FIG. 8 illustrates a layout of a semiconductor device including a transistor and an embedded resistor, in accordance with some embodiments.

The layout 80 shown in FIG. 8 pertains to a semiconductor device including a transistor and a resistor. The layout 80 can correspond to a top view perspective of a semiconductor device including a transistor and a resistor. The layout 80 includes an active region OD, gate structures G1, G2, G3, and G4, source conductors MD1, MD3, and MD5, drain conductors MD2 and MD4, dummy gate structures DG1 and DG2, and poly structures PD1 and PD2.

In some embodiments, the gate structures G1, G2, G3, and G4 can be electrically connected to the same voltage reference. The gate structures G1, G2, G3, and G4 can be electrically connected through upper-layered interconnections (not shown). The source conductors MD1, MD3, and MD5 can be electrically connected to the same voltage reference. The source conductors MD1, MD3, and MD5 can be electrically connected through upper-layered interconnections (not shown). The drain conductors MD2 and MD4 can be electrically connected to the same voltage reference. The drain conductors MD2 and MD4 can be electrically connected through upper-layered interconnections (not shown).

The layout 80 can be associated with a transistor having a multi-finger structure. The shorter source conductors MD1, MD3, and MD5 each provide higher resistance than the drain conductors MD2 and MD4. With the multi-finger structure shown in FIG. 8, the resistance of the equivalent resistor constituted by the source conductors MD1, MD3, and MD5 can be adjusted according to need. For example, when high resistance is needed in the source degeneration applications, a transistor can include a single short source conductor MD1. Alternatively, several short source conductors (e.g., MD1, MD3, and MD5) can be connected in parallel so as to achieve relatively lower resistance in another application. In still other embodiments, some of the short source conductors (e.g., MD1, MD3, and MD5) can be connected in series so as to achieve a target resistance.

In the embodiment shown in FIG. 8, a portion of each of the source conductors MD1, MD3, and MD5 extends beyond the area (e.g., defined by edges e3 and e4) of the active region OD. The source conductors MD1, MD3, and MD5 can be aligned, and each includes one edge aligned with the dashed line 802 and another edge aligned with the dashed line 804. Although a specific number (i.e., 3) of source conductors are depicted in FIG. 8, it can be contemplated that the number of source conductors can be adjusted in accordance with actual design needs. Similarly, the numbers of drain conductors and the gate structures can be adjusted in accordance with actual design needs. In some embodiments, the number of the gate structures can range from 2 to 300.

In some embodiments, the drain conductors MD2 and MD4 are disposed over a single active region OD. In some embodiments, the drains conductor MD2 and MD4 will not extend to another active region (not shown) that is adjacent to the active region OD depicted in FIG. 8.

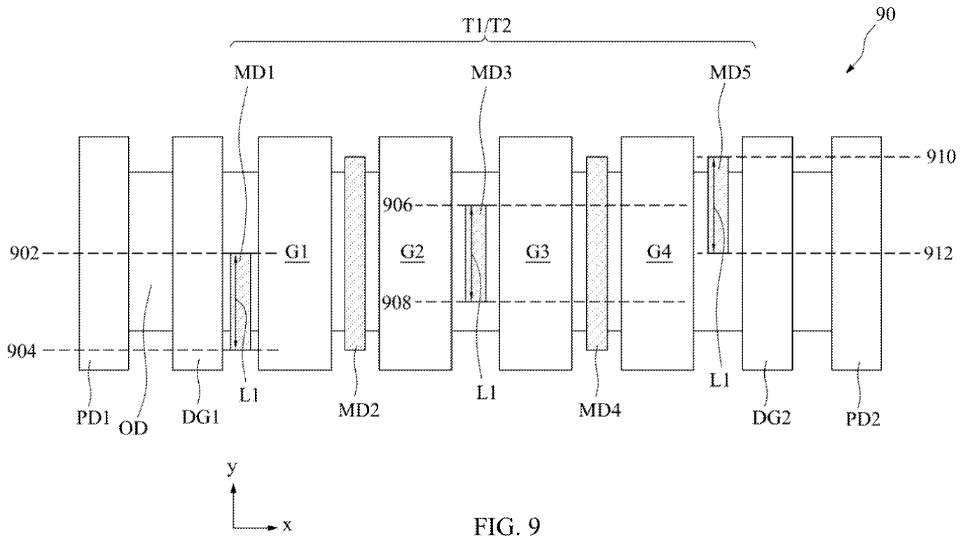

FIG. 9 illustrates a layout of a semiconductor device including a transistor and an embedded resistor, in accordance with some embodiments.

The layout 90 shown in FIG. 9 pertains to a semiconductor device including a transistor and a resistor. The layout 90 can correspond to a top view perspective of a semiconductor device including a transistor and a resistor. The layout 90 includes an active region OD, gate structures G1, G2, G3, and G4, source conductors MD1, MD3, and MD5, drain conductors MD2 and MD4, dummy gate structures DG1 and DG2, and poly structures PD1 and PD2.

In some embodiments, the gate structures G1, G2, G3, and G4 can be electrically connected to the same voltage reference. The gate structures G1, G2, G3, and G4 can be electrically connected through upper-layered interconnections (not shown). The source conductors MD1, MD3, and MD5 can be electrically connected to the same voltage reference. The source conductors MD1, MD3, and MD5 can be electrically connected through upper-layered interconnections (not shown). The drain conductors MD2 and MD4 can be electrically connected to the same voltage reference. The drain conductors MD2 and MD4 can be electrically connected through upper-layered interconnections (not shown).

The layout 90 can be associated with a transistor having a multi-finger structure. The shorter source conductors MD1, MD3, and MD5 each provides higher resistance than the drain conductors MD2 and MD4. With the multi-finger structure shown in FIG. 9, the resistance of the equivalent resistor constituted by the source conductors MD1, MD3, and MD5 can be adjusted according to need.

In the embodiment shown in FIG. 9, the source conductors MD1, MD3, and MD5 can be of an identical length (e.g., L1), and the source conductors MD1, MD3, and MD5 are misaligned. The source conductor MD1 includes two edges, respectively aligned with dashed lines 902 and 904. The source conductor MD3 includes two edges, respectively aligned with dashed lines 906 and 908. The source conductor MD5 includes two edges, respectively aligned with dashed lines 910 and 912. The position arrangements of the source conductors MD1, MD3, and MD5 elaborate the flexibility in implementation of the present disclosure.

Although a specific number (i.e., 3) of source conductors are depicted in FIG. 9, it can be contemplated that the number of source conductors can be adjusted in accordance with actual design needs. Similarly, the numbers of drain conductors and the gate structures can be adjusted in accordance with actual design needs. In some embodiments, the number of the gate structures can range from 2 to 300.

In some embodiments, the drain conductors MD2 and MD4 are disposed over a single active region OD. In some embodiments, the drains conductor MD2 and MD4 will not extend to another active region (not shown) that is adjacent to the active region OD depicted in FIG. 9.

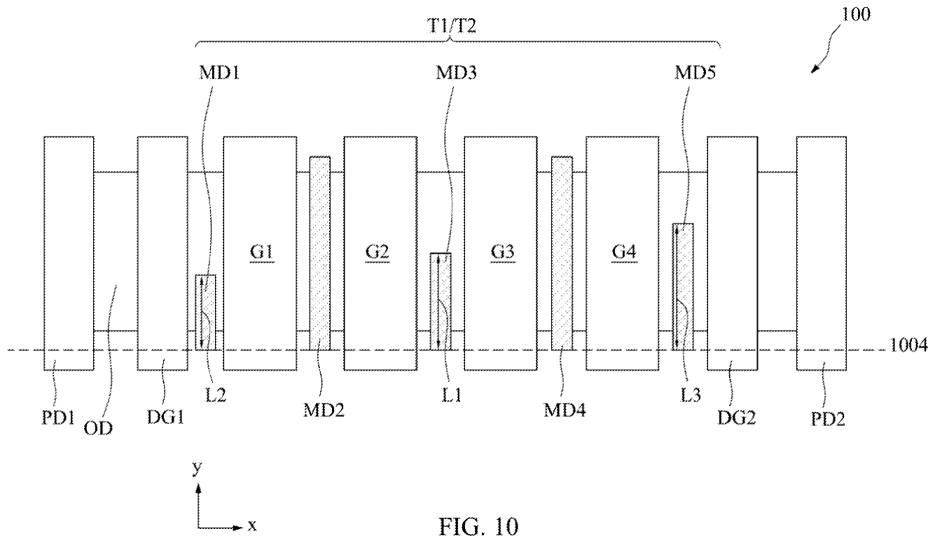

FIG. 10 illustrates a layout of a semiconductor device including a transistor and an embedded resistor, in accordance with some embodiments.

The layout 100 shown in FIG. 10 pertains to a semiconductor device including a transistor and a resistor. The layout 100 can correspond to a top view perspective of a semiconductor device including a transistor and a resistor. The layout 100 includes an active region OD, gate structures G1, G2, G3, and G4, source conductors MD1, MD3, and MD5, drain conductors MD2 and MD4, dummy gate structures DG1 and DG2, and poly structures PD1 and PD2.

In some embodiments, the gate structures G1, G2, G3, and G4 can be electrically connected to the same voltage reference. The gate structures G1, G2, G3, and G4 can be electrically connected through upper-layered interconnections (not shown). The source conductors MD1, MD3, and MD5 can be electrically connected to the same voltage reference. The source conductors MD1, MD3, and MD5 can be electrically connected through upper-layered interconnections (not shown). The drain conductors MD2 and MD4 can be electrically connected to the same voltage reference. The drain conductors MD2 and MD4 can be electrically connected through upper-layered interconnections (not shown).

The layout 100 can be associated with a transistor having a multi-finger structure. The shorter source conductors MD1, MD3, and MD5 each provides higher resistance than the drain conductors MD2 and MD4. With the multi-finger structure shown in FIG. 10, the resistance of the equivalent resistor constituted by the source conductors MD1, MD3, and MD5 can be adjusted according to need.

In the embodiment shown in FIG. 10, the source conductors MD1, MD3, and MD5 can be of different lengths (e.g., L1, L2, and L3). One edge of the source conductors MD1, MD3, and MD5 can be aligned with the dashed line 1004, and another edge of the source conductors MD1, MD3, and MD5 can be misaligned. The selections of the length of the source conductors MD1, MD3, and MD5 elaborate the flexibility in implementation of the present disclosure.

Although a specific number (i.e., 3) of source conductors are depicted in FIG. 10, it can be contemplated that the number of source conductors can be adjusted in accordance with actual design needs. Similarly, the numbers of drain conductors and the gate structures can be adjusted in accordance with actual design needs. In some embodiments, the number of the gate structures can range from 2 to 300.

In some embodiments, the drain conductors MD2 and MD4 are disposed over a single active region OD. In some embodiments, the drains conductor MD2 and MD4 will not extend to another active region (not shown) that is adjacent to the active region OD depicted in FIG. 10.

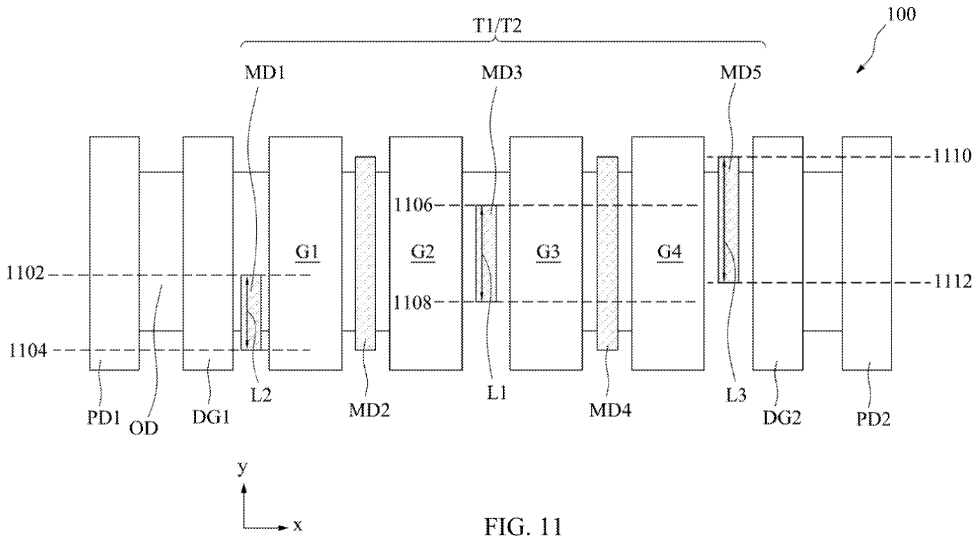

FIG. 11 illustrates a layout of a semiconductor device including a transistor and an embedded resistor, in accordance with some embodiments.

The layout 110 shown in FIG. 11 pertains to a semiconductor device including a transistor and a resistor. The layout 110 can correspond to a top view perspective of a semiconductor device including a transistor and a resistor. The layout 110 includes an active region OD, gate structures G1, G2, G3, and G4, source conductors MD1, MD3, and MD5, drain conductors MD2 and MD4, dummy gate structures DG1 and DG2, and poly structures PD1 and PD2.

In some embodiments, the gate structures G1, G2, G3, and G4 can be electrically connected to the same voltage reference. The gate structures G1, G2, G3, and G4 can be electrically connected through upper-layered interconnections (not shown). The source conductors MD1, MD3, and MD5 can be electrically connected to the same voltage reference. The source conductors MD1, MD3, and MD5 can be electrically connected through upper-layered interconnections (not shown). The drain conductors MD2 and MD4 can be electrically connected to the same voltage reference. The drain conductors MD2 and MD4 can be electrically connected through upper-layered interconnections (not shown).

The layout 110 can be associated with a transistor having a multi-finger structure. The shorter source conductors MD1, MD3, and MD5 each provide higher resistance than the drain conductors MD2 and MD4. With the multi-finger structure shown in FIG. 11, the resistance of the equivalent resistor constituted by the source conductors MD1, MD3, and MD5 can be adjusted according to need.

In the embodiment shown in FIG. 11, the source conductors MD1, MD3, and MD5 can be of different lengths (e.g., L1, L2, and L3), and the source conductors MD1, MD3, and MD5 are misaligned. The source conductor MD1 includes two edges, respectively aligned with dashed lines 1102 and 1104. The source conductor MD3 includes two edges, respectively aligned with dashed lines 1106 and 1108. The source conductor MD5 includes two edges, respectively aligned with dashed lines 1110 and 1112. The position/length arrangements of the source conductors MD1, MD3, and MD5 elaborate the flexibility in implementation of the present disclosure.

Although a specific number (i.e., 3) of source conductors are depicted in FIG. 11, it can be contemplated that the number of source conductors can be adjusted in accordance with actual design needs. Similarly, the numbers of drain conductors and the gate structures can be adjusted in accordance with actual design needs. In some embodiments, the number of the gate structures can range from 2 to 300.

In some embodiments, the drain conductors MD2 and MD4 are disposed over a single active region OD. In some embodiments, the drains conductor MD2 and MD4 will not extend to another active region (not shown) that is adjacent to the active region OD depicted in FIG. 11.

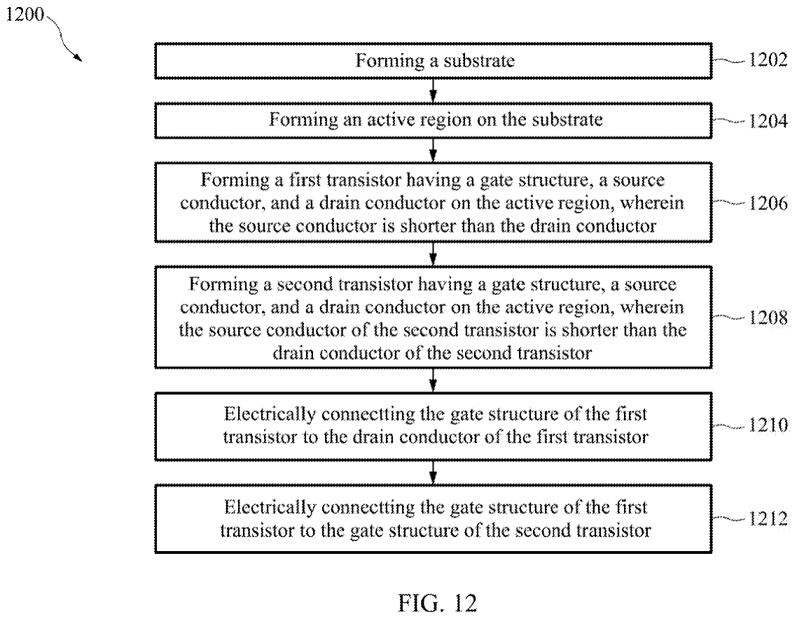

FIG. 12 is a flowchart of a method of manufacturing a semiconductor device, in accordance with some embodiments.

FIG. 12 is a flowchart of a method 1200 of manufacturing a semiconductor device, in accordance with some embodiments. The method 1200 is operable to form a current mirror circuit (e.g., the 20 current mirror circuit shown in FIG. 2) that includes a transistor having an embedded resistor, as discussed in accordance with the layouts 30, 50, 70, 80, 90, 100, 110 of FIGS. 3, 5, 7, 8, 9, 10, and 11.

In some embodiments, the operations of method 1200 are performed in the order depicted in FIG. 12. In some embodiments, the operations of method 1200 are performed in an order other than that depicted in FIG. 12 and/or two or more operations of method 1200 are performed simultaneously. In some embodiments, one or more additional operations are performed before, during, and/or after the operations of method 1200.

In operation 1202, a substrate is formed. In operation 1204, an active region is formed on the substrate. In some embodiments, the active region may correspond to the active region OD of FIGS. 3, 4A, 4B, and 5-11.

In operation 1206, a first transistor having a gate structure, a source conductor, and a drain conductor is formed on the active region, wherein the source conductor is shorter than the drain conductor. In some embodiments, the first transistor formed in operation 1206 may correspond to the transistor T1 of the current mirror circuit 20, wherein the first transistor is manufactured in accordance with one of the layouts 30, 50, 70, 80, 90, 100, 110 of FIGS. 3, 5, 7, 8, 9, 10, and 11.

In operation 1208, a second transistor having a gate structure, a source conductor, and a drain conductor is formed on the active region, wherein the source conductor of the second transistor is shorter than the drain conductor of the second transistor. In some embodiments, the second transistor formed in operation 1208 may correspond to the transistor T2 of the current mirror circuit 20, wherein the second transistor is manufactured in accordance with one of the layouts 30, 50, 70, 80, 90, 100, 110 of FIGS. 3, 5, 7, 8, 9, 10, and 11.

In operation 1210, the gate structure of the first transistor to the drain conductor of the first transistor are electrically connected. The gate structure of the first transistor can also be referred to as a gate terminal. In operation 1212, the gate structure of the first transistor to the gate structure of the second transistor are electrically connected. The gate structure of the second transistor can also be referred to as a gate terminal.

According to some embodiments, a semiconductor device is provided. The semiconductor device includes a substrate, an active region on the substrate, and a first transistor having a gate structure, a source conductor, and a drain conductor disposed on the active region, wherein the drain conductor and the source conductor are disposed on opposite sides of the gate structure, and the source conductor is shorter than the drain conductor.

According to some embodiments, a semiconductor device is provided. The semiconductor device includes a substrate and a plurality of fin structures extending from the substrate. The semiconductor device further includes a plurality of source/drain structures, each covers a portion of one of the plurality of fin structures. The semiconductor device further includes a first transistor having a gate structure, a drain conductor, and a source conductor disposed on the substrate, wherein the drain conductor and the source conductor are disposed on opposite sides of the gate structure, the drain conductor contacts each of the source/drain structures; and the source conductor is isolated from at least one of the source/drain structures.

According to other embodiments, a method of manufacturing a semiconductor device is provided. The method comprises forming a substrate and forming an active region on the substrate. The method further comprises forming a first transistor having a gate structure, a source conductor, and a drain conductor on the active region, wherein the drain conductor and the source conductor are disposed on opposite sides of the gate structure, and wherein the source conductor is shorter than the drain conductor.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor device, comprising:
a substrate;
an active region on the substrate;
a first transistor having a gate structure, a source conductor, and a drain conductor disposed on the active region, wherein
the drain conductor and the source conductor are disposed on opposite sides of the gate structure; and
the source conductor is shorter than the drain conductor.

2. The semiconductor device of claim 1, wherein a first edge of the source conductor is aligned with a first edge of the drain conductor, and a second edge of the source conductor is misaligned with a second edge of the drain conductor.

3. The semiconductor device of claim 1, wherein a first edge of the source conductor is misaligned with a first edge of the drain conductor, and a second edge of the source conductor is misaligned with a second edge of the drain conductor.

4. The semiconductor device of claim 2, wherein the first edge of the source conductor is located outside the active region, and wherein the second edge of the source conductor is located between a first boundary and a second boundary of the active region.

5. The semiconductor device of claim 3, wherein the first edge of the source conductor is located between a first boundary and a second boundary of the active region, and wherein the second edge of the source conductor is located between the first boundary and the second boundary of the active region.

6. The semiconductor device of claim 3, wherein the first edge of the source conductor is spaced apart from a first boundary of the active region by a first distance, and wherein the second edge of the source conductor is spaced apart from a second boundary of the active region by a second distance identical to the second distance.

7. The semiconductor device of claim 1, further comprising:
a second transistor having a gate structure, a drain conductor, and a source conductor disposed on the active region, wherein
the gate structure of the first transistor is electrically connected to the drain conductor of the first transistor; and
the gate structure of the first transistor is electrically connected to the gate structure of the second transistor.

8. The semiconductor device of claim 7, wherein the source conductor of the second transistor is shorter than the drain conductor of the second transistor.

9. The semiconductor device of claim 8, wherein a first edge of the source conductor of the second transistor is aligned with a first edge of the drain conductor of the second transistor, and a second edge of the source conductor of the second transistor is misaligned with a second edge of the drain conductor of the second transistor.

10. The semiconductor device of claim 8, wherein a first edge of the source conductor of the second transistor is misaligned with a first edge of the drain conductor of the second transistor, and a second edge of the source conductor of the second transistor is misaligned with a second edge of the drain conductor of the second transistor.

11. The semiconductor device of claim 1, wherein the first transistor further comprising:
a second gate structure disposed adjacent to the drain conductor;
a second source conductor disposed adjacent to second gate structure, wherein
the second gate structure is electrically connected to the gate structure;
the second source conductor is electrically connected to the source conductor; and
the second source conductor is shorter than the drain conductor.

12. A semiconductor device, comprising:
a substrate;
a plurality of fin structures extending from the substrate;
a plurality of source/drain structures, each covers a portion of one of the plurality of fin structures; and
a first transistor having a gate structure, a drain conductor, and a source conductor disposed on the substrate, wherein
the drain conductor and the source conductor are disposed on opposite sides of the gate structure;
the drain conductor contacts each of the source/drain structures; and
the source conductor is isolated from at least one of the source/drain structures.

13. The semiconductor device of claim 12, wherein the source conductor is shorter than the drain conductor in the top view perspective.

14. The semiconductor device of claim 12, wherein a first edge of the source conductor is aligned with a first edge of the drain conductor, and a second edge of the source conductor is misaligned with a second edge of the drain conductor.

15. The semiconductor device of claim 12, wherein a first edge of the source conductor is misaligned with a first edge of the drain conductor, and a second edge of the source conductor is misaligned with a second edge of the drain conductor.

16. The semiconductor device of claim 12, wherein the first transistor further comprising:
a second gate structure disposed adjacent to the drain conductor;
a second source conductor disposed adjacent to second gate structure, wherein
the second gate structure is electrically connected to the gate structure;
the second source conductor is electrically connected to the source conductor; and
the second source conductor is shorter than the drain conductor in the top view perspective.

17. The semiconductor device of claim 16, wherein the second source conductor is isolated from at least one of the source/drain structures.

18. A method of manufacturing a semiconductor device, comprising:
forming a substrate;
forming an active region on the substrate;
forming a first transistor having a gate structure, a source conductor, and a drain conductor on the active region, wherein
the drain conductor and the source conductor are disposed on opposite sides of the gate structure; and
the source conductor is shorter than the drain conductor.

19. The method of claim 18, wherein a first edge of the source conductor is aligned with a first edge of the drain conductor, and a second edge of the source conductor is misaligned with a second edge of the drain conductor.

20. The method of claim 18, wherein a first edge of the source conductor is misaligned with a first edge of the drain conductor, and a second edge of the source conductor is misaligned with a second edge of the drain conductor.
